(19) United States
(12) Patent Application Publication
(10) Pub. No.: US 2025/0323113 A1
(43) Pub. Date: Oct. 16, 2025

(54) THERMAL MANAGEMENT OF HIGH-POWER DEVICES AND STRUCTURES THEREOF

(71) Applicant: Qorvo US, Inc., Greensboro, NC (US)

(72) Inventors: Md Hasnine, Wylie, TX (US); Neftali Salazar, Murphy, TX (US)

(21) Appl. No.: 19/093,659

(22) Filed: Mar. 28, 2025

Related U.S. Application Data
(60) Provisional application No. 63/632,239, filed on Apr. 10, 2024.

(51) Int. Cl. H01L 23/367; H01L 21/56; H01L 23/00; H01L 23/31; H01L 23/373; H01L 23/66; H01L 25/16

(52) U.S. Cl. CPC H01L 23/367; H01L 21/561; H01L 21/565; H01L 23/3135; H01L 23/3731; H01L 23/3736; H01L 23/66; H01L 24/32; H01L 24/94; H01L 24/96; H01L 25/16; H01L 2224/32225; H01L 2224/32245; H01L 2224/94; H01L 2224/96; H01L 2924/1421

(57) ABSTRACT

One aspect of the present disclosure pertains to a chip module including an oversized heat spreader that supports thermal cooling of an integrated circuit (IC) die. The chip module includes a substrate, the IC die attached to the substrate, and a heat spreader coupled to a backside of the IC die. In some embodiments, the IC die has a first surface area, and the heat spreader has a second surface area that is at least twice as large as the first surface area.

### CROSS-REFERENCE TO RELATED APPLICATIONS

The present application claims the benefit of U.S. Provisional Application No. 63/632,239, entitled “THERMAL MANAGEMENT OF HIGH-POWER DEVICES AND STRUCTURES THEREOF” and filed on Apr. 10, 2024, which is incorporated herein by reference in its entirety.

### FIELD OF THE DISCLOSURE

The technology disclosed herein relates generally to thermal management of high-power semiconductor devices, and more particularly to heat dissipation of high-power radio frequency (RF) devices.

### BACKGROUND

High-power radio frequency (RF) devices, and specifically gallium nitride (GaN)-based high-power RF devices, provide significant advantages such as high breakdown voltage, high power density, high operating and switching frequency, and high thermal conductivity, among others. GaN RF devices are attractive for use in a wide range of applications such as in radars, telecommunications, base stations, power amplifiers, etc.

The downscaling of GaN RF device dimensions, while boosting device performance, has also increased power density, and resulted in concentrated heat fluxes within the device. More particularly, device heating and increased junction temperature have become vital considerations due to their potential to negatively impact device performance and reliability. Thermal management via passive heat sinks alone is insufficient to dissipate the highly concentrated heat fluxes produced by such devices. Additionally, further challenges are presented when the thermal budget is limited or restricted and the use of active heat sinks (e.g., such as forced air cooling, pin fin heat sinks, or liquid cooling solutions) is not permitted. Thus, existing thermal management techniques have not proved entirely satisfactory in all respects.

### SUMMARY

Example aspects of the present disclosure provide oversized heat spreaders, and related methods, that support thermal cooling of high-power radio frequency (RF) integrated circuit (IC) die, among others. In an example, an IC die is attached to a discrete, oversized semiconductor or metal heat spreader using a wafer-to-wafer or die-to-wafer bonding process. The heat spreader may include a SiC heat spreader, or other metal or composite heat spreader. The heat spreader may have a total surface area that is about 2-3 times larger than, or at least twice as large as, a total surface area of the IC die to which it is attached (e.g., from a top-down view). The oversized heat spreader effectively serves to lower the junction temperature of the IC die, and more specifically serves to lower the junction temperature of high-power GaN RF devices. By way of example, the IC die and attached heat spreader may then be bonded to a package substrate (e.g., using a flip-chip die bonding process). Thereafter, underfill and molding processes may be performed as part of a packaging process, and an external heat sink may optionally be attached to a topside of the package. In some embodiments, a plurality of IC die may be attached to a continuous heat spreader using the wafer-to-wafer or die-to-wafer bonding process, followed by bonding of the plural IC die and continuous heat spreader to a package substrate. In addition to the wafer-level bonding of an oversized heat spreader to one or more IC die, an additional large, continuous heat spreader may be attached at the package level to further increase the thermal performance of high-power GaN RF devices.

In one aspect, a chip module includes a package substrate, an IC die attached to the package substrate, and a heat spreader coupled to a backside of the IC die. In some embodiments, the IC die has a first surface area, and the heat spreader has a second surface area that is at least twice as large as the first surface area.

In some embodiments, the second surface area is 2-3 times larger than the first surface area.

In some embodiments, the heat spreader is coupled to the backside of the IC die along a first surface of the heat spreader, the first surface being substantially flat.

In some embodiments, the chip module further includes one or more surface mount devices (SMDs) attached to the package substrate in regions of the package substrate underneath portions of the heat spreader that overhang lateral ends of the IC die.

In some embodiments, the heat spreader is coupled to the backside of the IC die through a wafer-level bond including a thermally conductive bonding layer.

In some embodiments, the heat spreader includes a SiC heat spreader, a Cu heat spreader, a CPC heat spreader, or an AlN heat spreader.

In some embodiments, the coupled heat spreader and IC die collectively provide a die-heat spreader assembly, and the die-heat spreader assembly is attached to the package substrate along a frontside of the IC die.

In some embodiments, the coupled heat spreader and IC die collectively provide a die-heat spreader assembly, and the chip module further includes a mold compound that encapsulates the die-heat spreader assembly while a top surface of the die-heat spreader assembly remains exposed.

In some embodiments, the chip module further includes an external heat sink coupled to the exposed top surface of the die-heat spreader assembly.

In another aspect, a method includes attaching a backside of a die to a first surface of a heat spreader to form a die-heat spreader assembly, where the heat spreader has a first surface area that is at least twice as large as a second surface area of the die. In some embodiments, the method further includes bonding the die-heat spreader assembly to a substrate, where the die-heat spreader assembly is bonded to the substrate along a frontside of the die. In some embodiments, the method further includes performing a molding process to encapsulate the die-heat spreader assembly, where after the molding process a second surface of the heat spreader, opposite the first surface of the heat spreader, remains exposed.

In some embodiments, the first surface area is 2-3 times larger than the second surface area.

In some embodiments, the first surface of the heat spreader is substantially flat.

In some embodiments, the method further includes prior to the performing the molding process, attaching one or more SMDs to the substrate in regions of the substrate underneath portions of the heat spreader that overhang lateral ends of the die.

In some embodiments, the method further includes prior to the performing the molding process, performing an underfill process to fill gaps between the die and the substrate.

In some embodiments, the method further includes after performing the molding process, coupling an external heat sink to the exposed second surface of the heat spreader.

In some embodiments, the attaching the backside of the die to the first surface of the heat spreader includes a wafer-level bonding process, and the coupling the external heat sink to the exposed second surface of the heat spreader includes a package level bonding process.

In another aspect, a wireless communication device includes an antenna, a duplexer coupled to the antenna, and a power amplifier selectively coupled to the antenna through the duplexer. In some embodiments, the power amplifier includes an IC die disposed within a chip module. In some embodiments, the chip module includes the IC die attached to a substrate, and a heat spreader coupled to a backside of the IC die, where the IC die has a first surface area, and where the heat spreader has a second surface area that is at least twice as large as the first surface area.

In some embodiments, the IC die includes a high-power radio frequency (RF) device.

In some embodiments, the chip module further includes one or more SMDs attached to the substrate in regions of the substrate underneath portions of the heat spreader that overhang lateral ends of the IC die.

In some embodiments, the heat spreader includes a SiC heat spreader, a Cu heat spreader, a CPC heat spreader, or an AlN heat spreader.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a flow chart of a method of using a discrete oversized heat spreader attached to an IC die for cooling of the IC die, according to some embodiments.

FIGS. 2, 3, 4, 5, and 5A illustrate cross-section views of a discrete chip module at various stages of processing according to the method of FIG. 1, according to some embodiments.

FIG. 6 illustrates a cross-section view of a multichip module processed according to an alternative embodiment of the method of FIG. 1, in accordance with some embodiments.

FIG. 7 illustrates a flow chart of a method of using a continuous oversized heat spreader attached to a plurality of IC die for cooling of the plurality of IC die, according to some embodiments.

FIGS. 8, 9, and 10 illustrate cross-section views of a multichip module at various stages of processing according to the method of FIG. 7, according to some embodiments.

FIG. 11 illustrates a flow chart of an alternative method of using oversized heat spreaders attached to a plurality of IC die for cooling of the plurality of IC die, according to some embodiments.

FIGS. 12, 13, and 14 illustrate cross-section views of a multichip module at various stages of processing according to the method of FIG. 11, according to some embodiments.

FIG. 15 illustrates a cross-section view of a multichip module processed according to an alternative embodiment of the method of FIG. 7, in accordance with some embodiments.

FIG. 16 illustrates a flow chart of another alternative method of using oversized heat spreaders attached to a plurality of IC die for cooling of the plurality of IC die, according to some embodiments.

FIGS. 17, 18, 19, and 20 illustrate cross-section views of a multichip module at various stages of processing according to the method of FIG. 16, according to some embodiments.

FIG. 21 illustrates a block diagram of an exemplary wireless communication device, according to some aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be+/−15% by one of ordinary skill in the art. Further, disclosed dimensions of the different features can implicitly disclose dimension ratios between the different features. Still further, the present disclosure may repeat reference numerals and/or letters in the various examples. This repetition is for the purpose of simplicity and clarity and does not in itself dictate a relationship between the various embodiments and/or configurations discussed.

As power demands for high-power gallium nitride (GaN) radio frequency (RF) devices have increased, effective thermal management techniques have become increasingly complex. If the heat generated by the RF device cannot be dissipated efficiently, then device performance and reliability may be substantially degraded. To this end, a number of different thermal management strategies have been pursued with varying degrees of effectiveness. In one example, thermal management using passive heat sinks alone may not be sufficient to dissipate the highly concentrated heat fluxes produced by high-power GaN RF devices. In another example, such as when the thermal budget is limited or restricted, the use of active heat sinks (e.g., such as forced air cooling, pin fin heat sinks, or liquid cooling solutions) may not be permitted. In still another example, a wafer-to-wafer bonding process may provide for the addition of a semiconductor heat spreader on top of a device to dissipate heat through the top and is compatible with the addition of an external heat sink. However, wafer-to-wafer bonding enables only the addition of heat spreader having a size that is the same as a size of the die to which it is attached. As a result, the junction temperature cannot effectively be lowered. Thus, existing thermal management techniques have not proved entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments discussed herein include oversized heat spreaders, and related methods, that support thermal cooling of IC die and that effectively serve to overcome various shortcomings of existing methods. In some embodiments, a backside of an IC die (e.g., such as a GaN die or a SiC die) is attached to a discrete, oversized semiconductor or metal heat spreader using a wafer-to-wafer or die-to-wafer bonding process. In various examples, the heat spreader may include a SiC heat spreader. In other examples, the heat spreader may include a metal heat spreader or composite heat spreader such as copper (Cu), a copper-molybdenum-copper (CPC) heat spreader, or an aluminum nitride (AlN) heat spreader, among others. The heat spreader, by way of example, may have a total surface area that is about 2-3 times larger than a total surface area of the IC die to which it is attached. In accordance with embodiments of the present disclosure, the oversized heat spreader effectively serves to lower the junction temperature of the IC die, and more specifically serves to lower the junction temperature of high-power GaN RF devices. By way of example, the IC die and attached heat spreader may then be bonded to a package substrate (e.g., such as a laminate substrate) using a flip-chip die bonding process, where copper pillars on a frontside of the IC die are coupled to respective pads on a surface of the package substrate. Thereafter, underfill and molding processes may be performed as part of a packaging process, and an external heat sink may optionally be attached to a topside of the package. In some embodiments, backsides of a plurality of IC die may be attached to a large, continuous heat spreader using the wafer-to-wafer or die-to-wafer bonding process, followed by bonding of the plural IC die and continuous heat spreader to a package substrate (e.g., using a flip-chip die bonding process). In accordance with some embodiments, and in addition to the wafer-level bonding of an oversized heat spreader to one or more IC die, an additional large, continuous heat spreader may be attached at the package level to further increase the thermal performance of high-power GaN RF devices. Additional details of embodiments of the present disclosure are provided below, and additional benefits and/or other advantages will become apparent to those skilled in the art having benefit of the present disclosure.

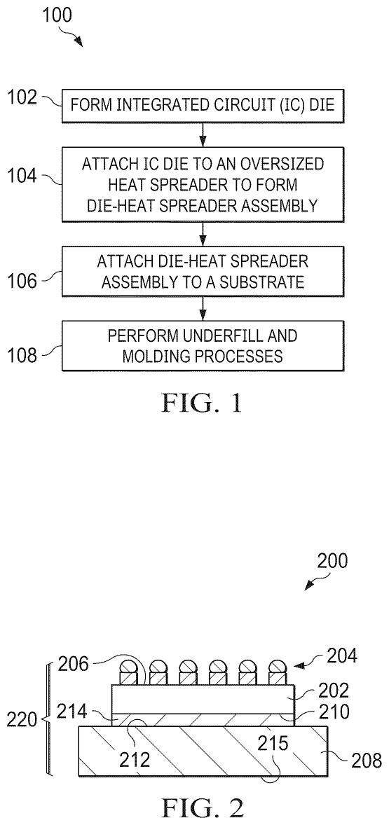

Referring to FIG. 1, illustrated is a method 100 of using a discrete oversized heat spreader attached to an IC die for cooling of the IC die, in accordance with some embodiments. The method 100 is described below in more detail with reference to FIGS. 2-5, which illustrate cross-section views of a discrete chip module 200 at various stages of processing according to the method 100. Moreover, it will be understood that additional process steps may be implemented before, during, and after the method 100, and some process steps described may be replaced or eliminated in accordance with various embodiments of the method 100.

The method 100 begins at block 102 where an IC die 202 is formed. With reference to FIG. 2, in an embodiment of block 102, the IC die 202 may include a high-power RF device such as a GaN RF device. More generally, in various examples, the IC die 202 may include a semiconductor device formed on a substrate including GaN, SiC, GaAs, or a combination thereof. As shown, the IC die 202 may include a plurality of conductive bumps 204 formed over a frontside 206 of the IC die 202, to facilitate subsequent bonding to a package substrate (e.g., via a flip-chip bonding process). In some examples, the conductive bumps 204 may include copper pillars with a Sn—Ag cap formed over a top of each of the copper pillars. Formation of the conductive bumps 204 may generally be completed at a wafer-level (e.g., before dicing of individual die), after which a dicing process is performed to provide the individual IC die 202.

The method 100 proceeds to block 104 where the IC die 202 is attached to an oversized heat spreader 208. Still referring to FIG. 2, in an embodiment of block 104, the IC die 202 is attached to the heat spreader 208 via a backside 210 of the IC die 202. The heat spreader 208, in some examples, may include a SiC heat spreader, a Cu heat spreader, a CPC heat spreader, or an AlN heat spreader, among others.

As part of the attachment process of block 104, a top surface 212 of the heat spreader 208, which is substantially flat (e.g., without cavities), may initially be coated with a conductive layer (not shown) such as a Au-plated layer. The conductive layer formed on the top surface 212 of the heat spreader 208 may be patterned, in some examples, using a combination of photolithographic patterning and etching (e.g., such as using Au etching, laser ablation, or the like), such that the patterned conductive layer has a similar surface area as the IC die 202. Thereafter, a thermally conductive bonding layer 214 may be used to attach the backside 210 of the IC die 202 to the patterned conductive layer on the top surface 212 of the heat spreader 208. In some cases, the thermally conductive bonding layer 214 may include a gold-based preform such as Au, AuSn, and the like. In some examples, the thermally conductive bonding layer 214 may include a high thermal conductivity sinter material such as an Ag—Cu sinter material, or similar high thermal conductivity sinter material. A reflow or curing process may then be performed to complete the bond between the IC die 202 and the heat spreader 208 to form a die-heat spreader assembly 220. As previously discussed, and in some embodiments, the heat spreader 208 may have a total surface area that is about 2-3 times larger than a total surface area of the IC die 202 to which it is attached. As a result, the thermally conductive bonding layer 214 and the oversized heat spreader 208 provide a thermal path to draw heat away from the IC die 202 and effectively lower the junction temperature of the IC die 202.

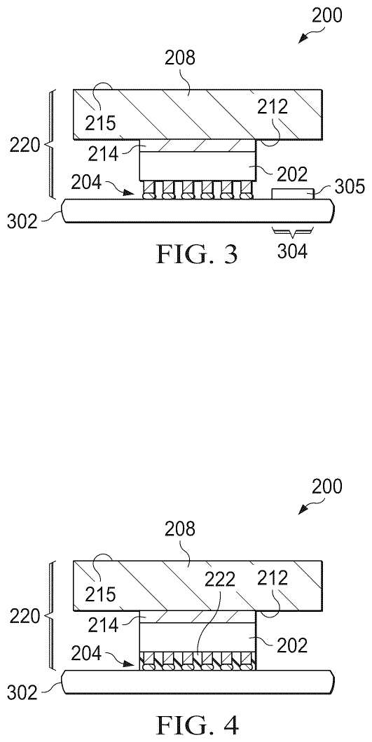

After attaching the oversized heat spreader 208 to the IC die 202 to form the die-heat spreader assembly 220, the method 100 proceeds to block 106 where the die-heat spreader assembly 220 is attached to a substrate 302. Referring to FIGS. 2 and 3, in an embodiment of block 106, the die-heat spreader assembly 220 is attached to the substrate 302 using a flip-chip bonding process. In some embodiments, the substrate 302 may include a package substrate (e.g., such as a laminate substrate), an interposer, or the like. The substrate 302 may also include a plurality of interconnect layers and conductive pads (not shown) connected thereto, where the conductive bumps 204 on the frontside 206 of the IC die 202 are coupled to respective pads on a surface of the substrate 302. For example, after aligning and contacting the conductive bumps 204 to respective pads on the substrate 302, a reflow process may be performed to heat/melt the conductive bumps 204 to allow conductive material of the conductive bumps 204 to spread uniformly across the respective pads on the substrate 302. It is noted that after the flip-chip bonding process of block 106, the top surface 212 of the heat spreader 208 is oriented face-down (towards the substrate 302), while a bottom surface 215 of the heat spreader 208 is oriented face-up (away from the substrate 302). Thus, after the flip-chip bonding process of block 106, the bottom surface 215 of the heat spreader 208 provides a top surface of the die-heat spreader assembly 220.

The method 100 then proceeds to block 108 where underfill and molding processes are performed. Referring to FIGS. 3-5, in an embodiment of block 108, an underfill material 222 (e.g., such as a polymer or liquid epoxy) is dispensed to fill gaps between the IC die 202 and the substrate 302, and to fill gaps between adjacent ones of the conductive bumps 204. By way of example, the underfill material 222 serves to enhance mechanical strength and reliability, mitigate thermal expansion mismatch between the IC die 202 and the substrate 302, and reduce thermal fatigue on the conductive bumps 204, among others. In at least some embodiments, after the flip-chip bonding process of block 106 and prior to forming the underfill material 222, one or more surface mount devices (SMDs) 305 may be attached to the substrate 302 in regions 304 of the substrate 302 adjacent to the IC die 202 and underneath portions of the heat spreader 208 that overhang (or extend beyond) lateral ends of the IC die 202. Generally, the SMDs may include passive devices such as resistors, capacitors, or inductors.

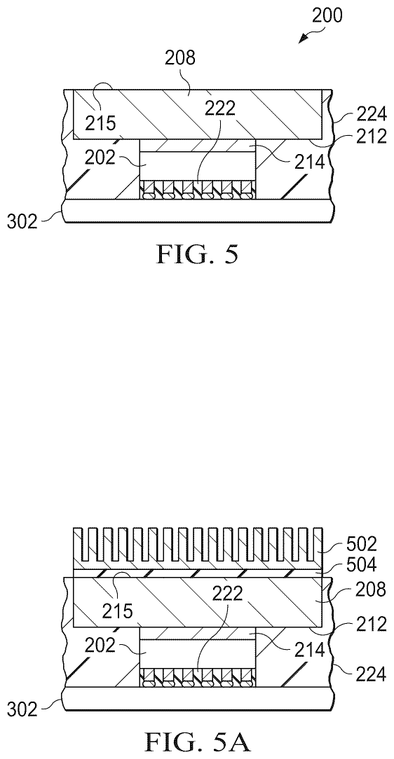

After forming and curing the underfill material 222, and in a further embodiment of block 108, a mold compound 224 is formed surrounding the die-heat spreader assembly 220 to encapsulate the die-heat spreader assembly 220. In some embodiments, the mold compound 224 may include a mold compound formed by a film-assisted molding (FAM) process, or by another suitable process. In some examples, after forming the mold compound 224 and in some embodiments, the top surface of the die-heat spreader assembly 220 (e.g., the bottom surface 215 of the heat spreader 208) may be substantially level with a top surface of the mold compound 224. However, regardless of whether the top surface of the die-heat spreader assembly 220 and the top surface of the mold compound 224 are level with each other, the top surface of the die-heat spreader assembly 220 (e.g., the bottom surface 215 of the heat spreader 208) may remain exposed after formation of the mold compound 224, thereby providing a thermal path for transferring heat away from the IC die 202. Stated another way, the discrete chip module 200 thus provides a package structure for top-side cooled package thermal management. Moreover, in some cases, an external heat sink 502, as shown in the exemplary embodiment of FIG. 5A, may optionally be attached to the exposed top surface of the die-heat spreader assembly 220 (e.g., the bottom surface 215 of the heat spreader 208). In some embodiments, the external heat sink 502 may be attached using a thermal interface material (TIM) layer 504, which may include a variety of different types of materials such as thermal gels, thermal grease, graphite, diamond, silver, aluminum nitride, boron nitride, alumina, silicon nitride, silicon carbide, aluminum nitride, ceramics, metals, and/or other thermally conductive materials or combinations thereof.

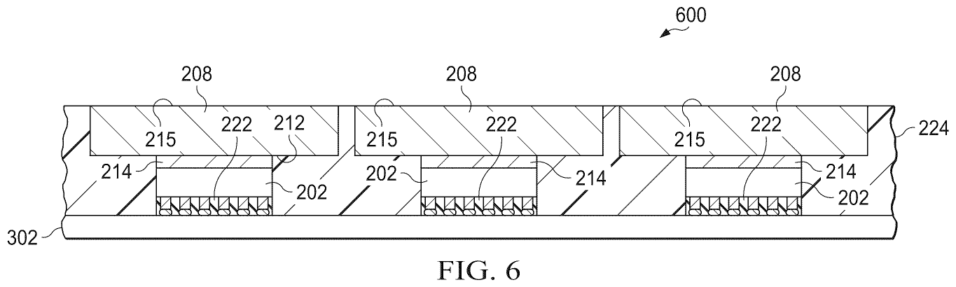

In an alternative embodiment of the method 100, and with reference to FIG. 6, a multichip module 600 may be fabricated in a similar manner as discussed above with reference to the method 100. As shown, each of a plurality of IC die 202 is attached to respective oversized heat spreaders 208 via the backside 210 of each of the IC die 202 to form discrete die-heat spreader assemblies 220, as discussed above with reference to blocks 102-104 of method 100. Each of the plural discrete die-heat spreader assemblies 220 is then attached to the substrate 302 using a flip-chip bonding process, as discussed above with reference to block 106 of method 100. After each of the plural discrete die-heat spreader assemblies 220 is attached to the substrate 302, underfill and molding processes may be performed, as discussed above with reference to block 108 of method 100. In some embodiments, each of the discrete die-heat spreader assemblies 220 is formed and subsequently attached to the substrate 302, for example, by sequentially repeating blocks 104-106 as many times as needed before performing the underfill and molding processes of block 108. In other embodiments, the plural discrete die-heat spreader assemblies 220 may be formed and attached to the substrate 302 simultaneously, after which the underfill and molding process is performed.

In the example of FIG. 6, each of the respective heat spreaders 208 may have a total surface area that is about 2-3 times larger than a total surface area of the particular IC die 202 to which the respective heat spreaders 208 are attached. While the plural IC die 202 of the multichip module 600 may have different sizes (e.g., such as different widths and/or different surface areas), in some embodiments, for purposes of the present example it is assumed that each of the IC die 202 have substantially the same size (e.g., same width and/or same surface area). Also, each of the plural IC die 202 may have substantially the same thickness. In some examples, each of the respective heat spreaders 208 in the multichip module 600 may have substantially the same size. However, in at least some cases, two or more of the heat spreaders 208 of the multichip module 600 may have different sizes, where the different sizes of respective heat spreaders 208 is based on respective amounts of heat generated by various devices (e.g., such as different high-power RF devices) formed within each of the particular IC die 202. For example, when a first IC die 202 generates more heat than a second IC die 202, a first heat spreader 208 attached to the first IC die 202 may be larger than a second heat spreader 208 attached to the second IC die 202. In a case where each of the IC die 202 of the multichip module 600 generates a different amount of heat, each of the respective heat spreaders 208 attached to particular ones of the IC die 202 may have different sizes. While some examples of providing different size heat spreaders 208 attached to respective IC die 202 generating different amounts of heat have been given, it will be understood that these examples are not meant to be limiting, and other embodiments may equally be employed without departing from the scope of the present disclosure. Further, while the multichip module 600 illustrates three IC die 202 and three die-heat spreader assemblies 220, other embodiments may include more or fewer IC die 202 and die-heat spreader assemblies 220.

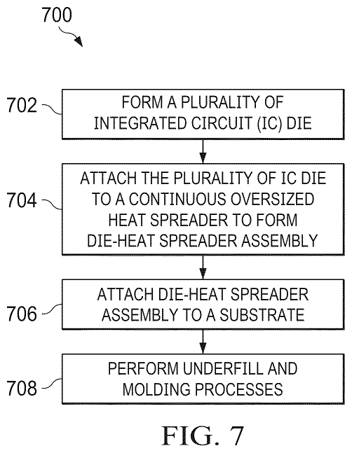

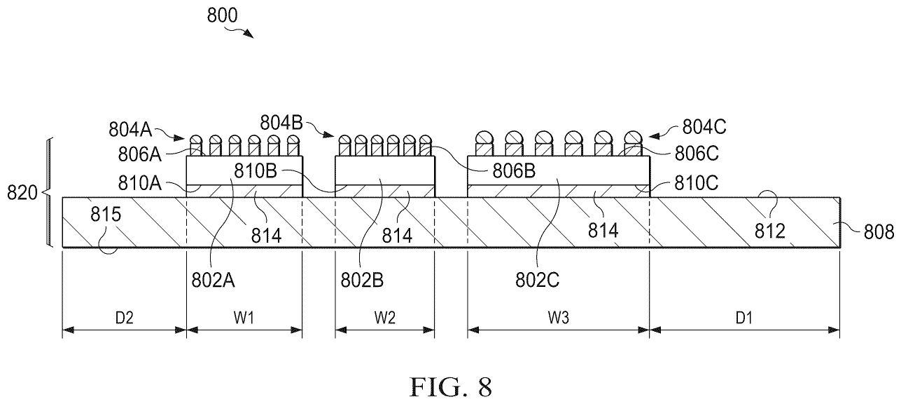

Referring now to FIG. 7, illustrated is a method 700 of using a continuous oversized heat spreader attached to a plurality of IC die for cooling of the plurality of IC die, in accordance with some embodiments. The method 700 is described below in more detail with reference to FIGS. 8-10, which illustrate cross-section views of a multichip module 800 at various stages of processing according to the method 700. Moreover, it will be understood that additional process steps may be implemented before, during, and after the method 700, and some process steps described may be replaced or eliminated in accordance with various embodiments of the method 700. Further, one or more aspects discussed above with reference to the method 100 may also apply to the method 700.

The method 700 begins at block 702 where a plurality of IC die 802A, 802B, 802C are formed. With reference to FIG. 8, in an embodiment of block 702, the IC die 802A, 802B, 802C may be similar to the IC die 202, discussed above, and may include a high-power RF device (e.g., such as a GaN RF device) or more generally a semiconductor device formed on a substrate including GaN, SiC, GaAs, or a combination thereof. To be sure, in some cases, at least one of the IC die 802A, 802B, 802C may include a high-power RF device, while the remaining IC die may include other types of high-power devices or non-high-power devices. Moreover, in various embodiments, the plurality of IC die 802A, 802B, 802C may be formed in different sizes, may come from different wafers, and may include different device types and/or circuit types. In the example shown, the IC die 802A has a first width W1, the IC die 802B has a second width W2 substantially equal to the first width W1, and the third IC die 802C has a third width W3 greater than each of the first and second widths W1, W2. Generally, each of the plurality of IC die 802A, 802B, 802C may have substantially the same thickness. As shown, each of the IC die 802A, 802B, 802C may include a plurality of conductive bumps 804A, 804B, 804C formed over frontsides 806A, 806B, 806C of respective ones of the plurality of IC die 802A, 802B, 802C, which may be substantially the same as the conductive bumps 204 formed over the frontside 206 of the IC die 202, discussed above.

The method 700 proceeds to block 704 where each of the plurality of IC die 802A, 802B, 802C is attached to a same continuous oversized heat spreader 808. Still referring to FIG. 8, in an embodiment of block 704, each of the plurality of IC die 802A, 802B, 802C is attached to the same continuous heat spreader 808 via respective backsides 810A, 810B, 810C of respective ones of the plurality of IC die 802A, 802B, 802C. The continuous heat spreader 808, in some examples, may include a SiC heat spreader, a Cu heat spreader, a CPC heat spreader, or an AlN heat spreader, among others. Further, the continuous heat spreader 808 may in some cases include a package-size heat spreader. That is, the continuous heat spreader 808 may have a width that extends across a substantial interior width of a package within which it is encapsulated.

As part of the attachment process of block 704, a top surface 812 of the continuous heat spreader 808, which is substantially flat (e.g., without cavities), may initially be coated with a conductive layer (not shown), such as a Au-plated layer. The conductive layer formed on the top surface 812 of the continuous heat spreader 808 may be patterned, in some examples, using a combination of photolithographic patterning and etching (e.g., such as using Au etching, laser ablation, or the like), such that the patterned conductive layer includes patterned regions corresponding to, and having similar surface areas as, the plurality of IC die 802A, 802B, 802C. Thereafter, a thermally conductive bonding layer 814, similar to the thermally conductive bonding layer 214 discussed above, may be used to attach the backsides 810A, 810B, 810C of respective ones of the plurality of IC die 802A, 802B, 802C to the patterned conductive layer on the top surface 812 of the continuous heat spreader 808. A reflow or curing process may then be performed to complete the bond between the plurality of IC die 802A, 802B, 802C and the continuous heat spreader 808 to form a die-heat spreader assembly 820. In some embodiments, the continuous heat spreader 808 may have a total surface area that is about 2-3 times larger than a total surface area of the plurality of IC die 802A, 802B, 802C to which it is attached. As a result, the thermally conductive bonding layer 814 and the continuous oversized heat spreader 808 provide a thermal path to draw heat away from each of the plurality of IC die 802A, 802B, 802C and effectively lower the junction temperature of each of the plurality of IC die 802A, 802B, 802C. In some cases, the overall size of the continuous heat spreader 808 (total surface area) may be determined based on a particular one of the plurality of IC die 802A, 802B, 802C that generates the most heat. As another example, assuming that the IC die 802C generates the most heat, the plurality of IC die 802A, 802B, 802C may be attached to the continuous heat spreader 808 such that the continuous heat spreader 808 overhangs the IC die 802C by a first distance D1 greater than a second distance D2 by which the continuous heat spreader 808 overhangs the IC die 802A.

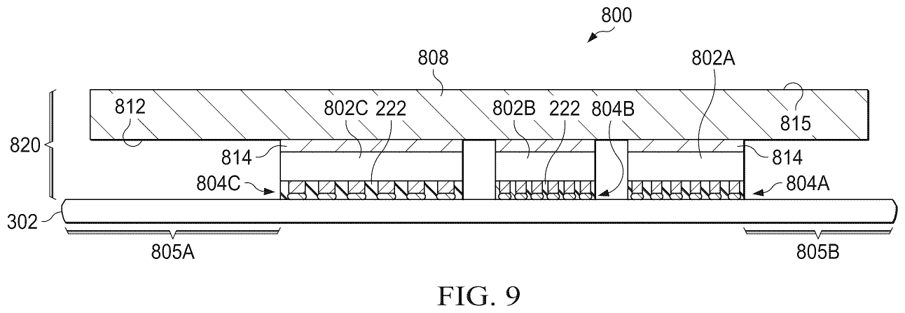

After attaching the continuous heat spreader 808 to the plurality of IC die 802A, 802B, 802C to form the die-heat spreader assembly 820, the method 700 proceeds to block 706 where the die-heat spreader assembly 820 is attached to the substrate 302. Referring to FIGS. 8 and 9, in an embodiment of block 706, the die-heat spreader assembly 820 is attached to the substrate 302 using a flip-chip bonding process. For example, the conductive bumps 804A, 804B, 804C formed over frontsides 806A, 806B, 806C of respective ones of the plurality of IC die 802A, 802B, 802C are coupled to respective pads on a surface of the substrate 302, similar to the example discussed above with reference to the discrete chip module 200. After the flip-chip bonding process of block 706, the top surface 812 of the continuous heat spreader 808 is oriented face-down (towards the substrate 302), while a bottom surface 815 of the continuous heat spreader 808 is oriented face-up (away from the substrate 302). Thus, after the flip-chip bonding process of block 706, the bottom surface 815 of the continuous heat spreader 808 provides a top surface of the die-heat spreader assembly 820.

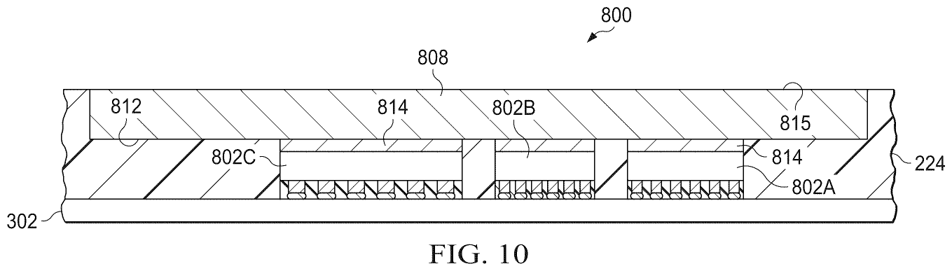

The method 700 then proceeds to block 708 where underfill and molding processes are performed. Referring to FIGS. 9 and 10, in an embodiment of block 708, the underfill material 222 (e.g., such as a polymer or liquid epoxy) is dispensed to fill gaps between each of the plurality of IC die 802A, 802B, 802C and the substrate 302, and to fill gaps between adjacent ones of the conductive bumps 804A, 804B, 804C. After the flip-chip bonding process of block 706 and prior to forming the underfill material 222, one or more SMDs may be formed in regions 805A, 805B of the substrate 302 adjacent to the plurality of IC die 802A, 802B, 802C and underneath portions of the continuous heat spreader 808 that overhang (or extend beyond) lateral ends of the plurality of IC die 802A, 802B, 802C. In particular, and with reference to the example shown, the region 805A (adjacent to the IC die 802C) may be larger than the region 805B (adjacent to the IC die 802A) due to the larger overhang of the IC die 802C (D1) by the continuous heat spreader 808 as compared to the smaller overhang of the IC die 802A (D2) by the continuous heat spreader 808. As a result, and in some embodiments, a greater number of SMDs may be attached to the substrate 302 in the region 805A as compared to the region 805B.

After forming and curing the underfill material 222, and in a further embodiment of block 708, the mold compound 224 may be formed surrounding the die-heat spreader assembly 820 to encapsulate the die-heat spreader assembly 820. As noted above, the mold compound 224 may include a mold compound formed by a film-assisted molding (FAM) process, or by another suitable process. In some examples, after forming the mold compound 224 and in some embodiments, the top surface of the die-heat spreader assembly 820 (e.g., the bottom surface 815 of the continuous heat spreader 808) may be substantially level with a top surface of the mold compound 224. However, regardless of whether the top surface of the die-heat spreader assembly 820 and the top surface of the mold compound 224 are level with each other, the top surface of the die-heat spreader assembly 820 (e.g., the bottom surface 815 of the continuous heat spreader 808) may remain exposed after formation of the mold compound 224, thereby providing a thermal path for transferring heat away from the plurality of IC die 802A, 802B, 802C. The multichip module 800 thus provides a package structure for top-side cooled package thermal management. Moreover, in some cases, an external heat sink (e.g., such as shown and described with reference to FIG. 5A) may optionally be attached to the exposed top surface of the die-heat spreader assembly 820 (e.g., the bottom surface 815 of the continuous heat spreader 808).

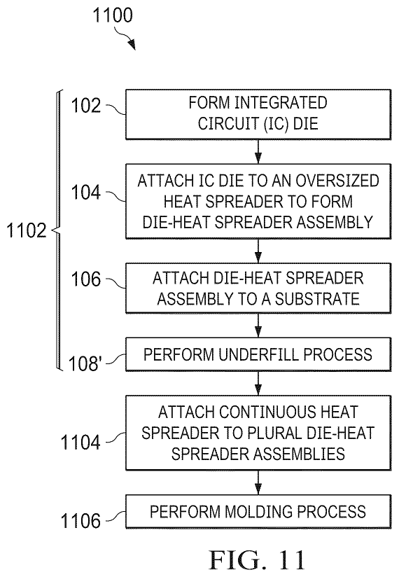

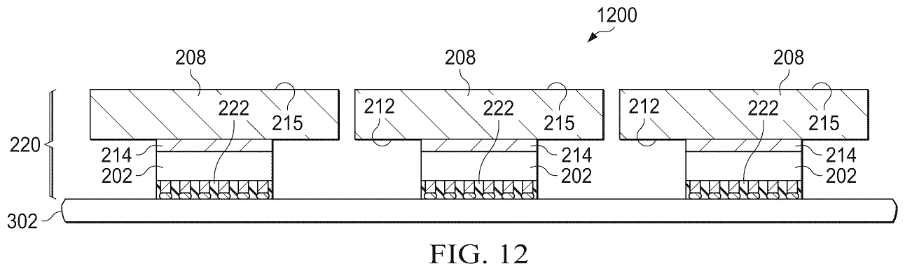

Referring to FIG. 11, illustrated is a method 1100 of using oversized heat spreaders attached to a plurality of IC die for cooling of the plurality of IC die, in accordance with some embodiments. The method 1100 is described below in more detail with reference to FIGS. 12-14, which illustrate cross-section views of a multichip module 1200 at various stages of processing according to the method 1100. Moreover, it will be understood that additional process steps may be implemented before, during, and after the method 1100, and some process steps described may be replaced or eliminated in accordance with various embodiments of the method 1100. Further, one or more aspects discussed above with reference to the method 100 may also apply to the method 1100.

In particular, the multichip module 1200 may be at least partially fabricated in a similar manner as discussed above with reference to the method 100. For example, the method 1100 begins at process 1102, which includes blocks 102-106, discussed above with reference to the method 100. Process 1102 of the method 1100 further includes block 108′, which includes the underfill formation process of block 108, discussed above. Thus, with reference to FIG. 12 and process 1102 of the method 1100, the multichip module 1200 may include a plurality of IC die 202 being attached to respective oversized heat spreaders 208 via the backside 210 of each of the IC die 202 to form discrete die-heat spreader assemblies 220 (as discussed with reference to blocks 102-104 of method 100). Generally, each of the plurality of IC die 202 may have substantially the same thickness. Each of the plural discrete die-heat spreader assemblies 220 is then attached to the substrate 302 using a flip-chip bonding process (as discussed with reference to block 106 of method 100). After each of the plural discrete die-heat spreader assemblies 220 is attached to the substrate 302, an underfill material 222 may be formed and cured (as discussed with reference to block 108 of method 100).

In some embodiments, each of the plural discrete die-heat spreader assemblies 220 is formed and subsequently attached to the substrate 302, for example, by sequentially repeating blocks 104-106 as many times as needed before performing the underfill process of block 108′. In other embodiments, the plural discrete die-heat spreader assemblies 220 may be formed and attached to the substrate 302 simultaneously, after which the underfill process is performed. Additionally, as previously described and prior to the underfill process, one or more SMDs may be formed in regions of the substrate 302 adjacent to the plurality of IC die 202.

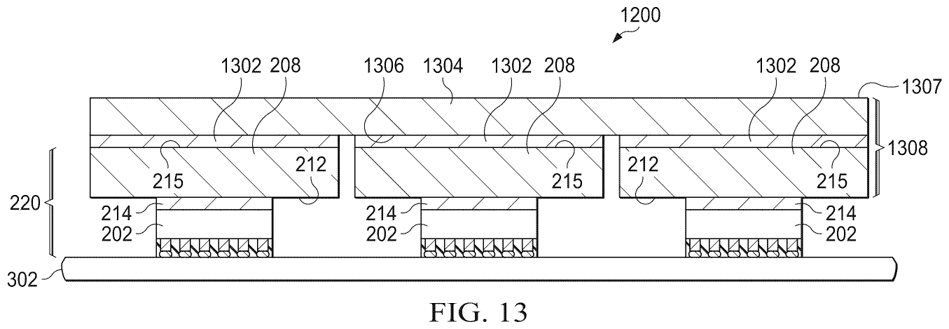

The method 1100 proceeds to block 1104 where a continuous heat spreader 1304 is attached to each of the plural discrete die-heat spreader assemblies 220 attached to the substrate 302. Referring to FIGS. 12 and 13, in an embodiment of block 1104, each of the plural discrete die-heat spreader assemblies 220 is attached to the same continuous heat spreader 1304 via exposed top surfaces of each of the plural die-heat spreader assemblies 220 (e.g., which is the bottom surfaces 215 of each of the plural discrete heat spreaders 208, now oriented upwards away from the substrate 302). The continuous heat spreader 1304, like the examples discussed above, may include a SiC heat spreader, a Cu heat spreader, a CPC heat spreader, or an AlN heat spreader, among others.

As part of the attachment process of block 1104, a surface 1306 of the continuous heat spreader 1304, which is substantially flat (e.g., without cavities), may initially be coated with a conductive layer (not shown), such as a Au-plated layer. The conductive layer formed on the surface 1306 of the continuous heat spreader 1304 may be patterned, in some examples, using a combination of photolithographic patterning and etching (e.g., such as using Au etching, laser ablation, or the like), such that the patterned conductive layer includes patterned regions corresponding to, and having similar surface areas as, the top surfaces of each of the plural die-heat spreader assemblies 220 (e.g., the bottom surfaces 215 of each of the plural discrete heat spreaders 208). Thereafter, a thermally conductive bonding layer 1302, similar to the thermally conductive bonding layer 214 discussed above, may be used to attach the top surfaces of each of the plural die-heat spreader assemblies 220 to the patterned conductive layer on the surface 1306 of the continuous heat spreader 1304, after appropriate positioning and aligning of the continuous heat spreader 1304 over the top surfaces of each of the plural die-heat spreader assemblies 220. In at least some cases, the thermally conductive bonding layer 1302 includes a silver (Ag) sinter paste. The thermally conductive bonding layer 1302 may also provide a thicker bondline and compensate for stack-up tolerances. A reflow or curing process may then be performed to complete the bond between the plural die-heat spreader assemblies 220 and the continuous heat spreader 1304 to form a stacked heat spreader assembly 1308. In some embodiments, use of the continuous heat spreader 1304 over the plural discrete heat spreaders 208, to form the stacked heat spreader assembly 1308, may be employed on multichip module for applications in which forced cooling is lacking but additional cooling is needed.

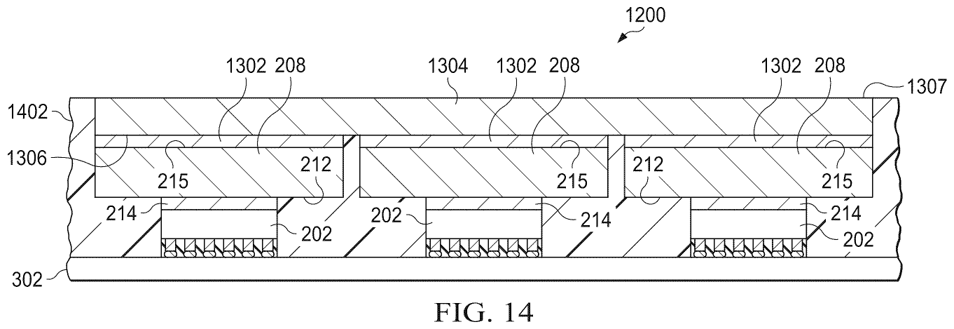

The method 1100 proceeds to block 1106 a molding process is performed, similar to the molding process of block 108 of method 100, discussed above. Referring to FIGS. 13 and 14, in an embodiment of block 1106, a mold compound 1402 (similar to the mold compound 224, discussed above) may be formed surrounding the plural die-heat spreader assemblies 220 and the continuous heat spreader 1304 to encapsulate the plural die-heat spreader assemblies 220 and the continuous heat spreader 1304. In some embodiments, the mold compound 1402 may include a mold compound formed by a film-assisted molding (FAM) process, or by another suitable process. In some examples, after forming the mold compound 1402 and in some embodiments, a surface 1307 of the continuous heat spreader 1304 (opposite the surface 1306) may be substantially level with a top surface of the mold compound 1402. However, regardless of whether the surface 1307 of the continuous heat spreader 1304 and the top surface of the mold compound 1402 are level with each other, the surface 1307 of the continuous heat spreader 1304 may remain exposed after formation of the mold compound 1402, thereby providing a thermal path for transferring heat away from the plurality of IC die 202. Moreover, in some cases, an external heat sink (e.g., such as shown and described with reference to FIG. 5A) may optionally be attached to the exposed surface 1307 of the continuous heat spreader 1304.

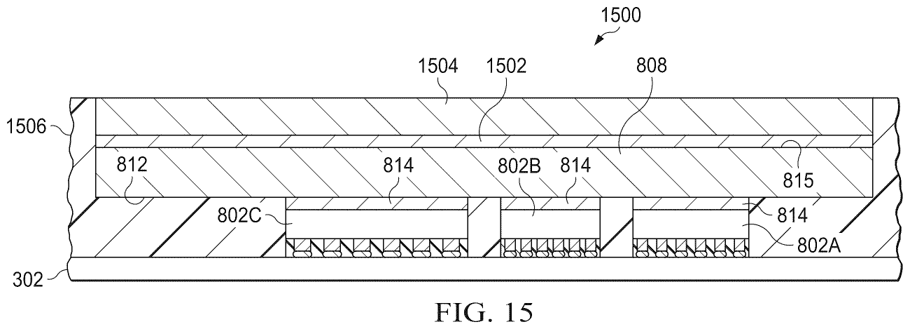

In an alternative embodiment of using a stacked heat spreader assembly, reference is made to FIG. 15, which illustrates a multichip module 1500. In some embodiments, the multichip module 1500 may be fabricated in a similar manner as discussed above with reference to the method 700. As shown, each of the plurality of IC die 802A, 802B, 802C is attached to the same continuous heat spreader 808 via respective backsides 810A, 810B, 810C of respective ones of the plurality of IC die 802A, 802B, 802C to form a die-heat spreader assembly 820, as discussed above with reference to blocks 702-704 of method 700. The die-heat spreader assembly 820 is then attached to the substrate 302 using a flip-chip bonding process, as discussed above with reference to block 706 of method 700. After the die-heat spreader assembly 820 is attached to the substrate 302, an underfill process may be performed, as discussed above with reference to block 708 of method 700. Prior to performing a molding process, and in some embodiments, another continuous heat spreader 1504 (similar to the continuous heat spreader 1304, discussed above) is attached to the top surface of the die-heat spreader assembly 820 (e.g., the bottom surface 815 of the continuous heat spreader 808) using a conductive bonding layer 1502, similar to the thermally conductive bonding layer 1302, discussed above. After attaching the continuous heat spreader 1504 to the continuous heat spreader 808, a molding process may be performed to provide a mold compound 1506 (similar to the mold compound 224, discussed above). In some cases, an external heat sink (e.g., such as shown and described with reference to FIG. 5A) may optionally be attached to an exposed surface of the continuous heat spreader 1504.

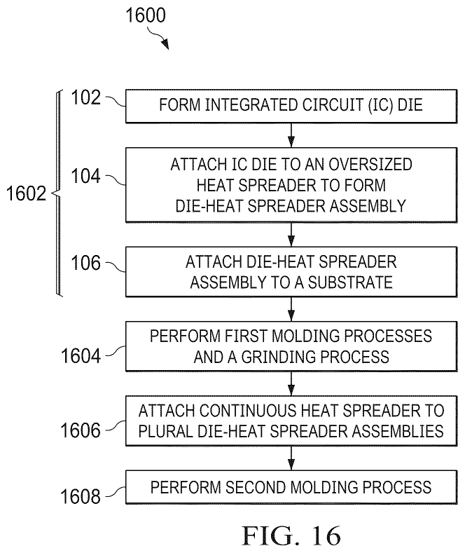

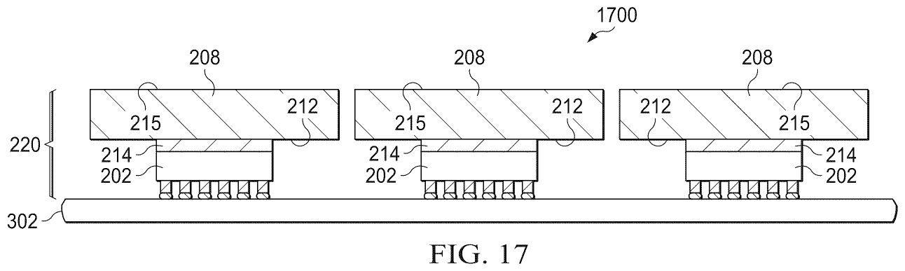

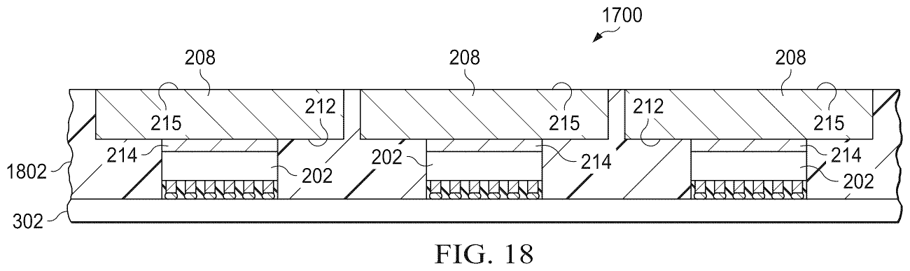

Referring to FIG. 16, illustrated is an alternative method 1600 of using oversized heat spreaders attached to a plurality of IC die for cooling of the plurality of IC die, in accordance with some embodiments. The method 1600 is described below in more detail with reference to FIGS. 17-20, which illustrate cross-section views of a multichip module 1700 at various stages of processing according to the method 1600. Moreover, it will be understood that additional process steps may be implemented before, during, and after the method 1600, and some process steps described may be replaced or eliminated in accordance with various embodiments of the method 1600. Further, one or more aspects discussed above with reference to the method 100 may also apply to the method 1600.

For example, the multichip module 1700 may be at least partially fabricated in a similar manner as discussed above with reference to the method 100. In an embodiment, the method 1600 begins at process 1602, which includes blocks 102-106, discussed above with reference to the method 100. Thus, with reference to FIG. 17 and process 1602 of the method 1600, the multichip module 1700 may include a plurality of IC die 202 being attached to respective oversized heat spreaders 208 via the backside 210 of each of the IC die 202 to form discrete die-heat spreader assemblies 220 (as discussed with reference to blocks 102-104 of method 100). Generally, each of the plurality of IC die 202 may have substantially the same thickness. Each of the plural discrete die-heat spreader assemblies 220 is then attached to the substrate 302 using a flip-chip bonding process (as discussed with reference to block 106 of method 100).

In some embodiments, each of the plural discrete die-heat spreader assemblies 220 is formed and subsequently attached to the substrate 302, for example, by sequentially repeating blocks 104-106 as many times as needed before proceeding with the method 1600. In other embodiments, the plural discrete die-heat spreader assemblies 220 may be formed and attached to the substrate 302 simultaneously, after which the method 1600 further proceeds. In some embodiments, one or more SMDs may be formed in regions of the substrate 302 adjacent to the plurality of IC die 202. It is noted that in some embodiments, after block 106 of process 1602, the process 1602 may further include an underfill process, such as the underfill formation process of block 108, discussed above.

The method 1600 proceeds to block 1604 where a first molding process and a grinding process are performed. Referring to FIGS. 17 and 18, in an embodiment of block 1604, a first molding process is performed to form a mold compound 1802 surrounding the plural discrete die-heat spreader assemblies 220 to encapsulate the plural discrete die-heat spreader assemblies 220. In some embodiments, the first molding process used to form the mold compound 1802 may include a compression molding process, or another suitable process. Further, in some cases, the first molding process may also form the mold compound 1802 over top surfaces of the plural discrete die-heat spreader assemblies 220 (e.g., which includes the bottom surfaces 215 of respective heat spreaders 208 of the plural discrete die-heat spreader assemblies 220). After the first molding process, a grinding process is performed to remove the mold compound 1802 from top surfaces of the plural discrete die-heat spreader assemblies 220, thereby exposing the bottom surfaces 215 of respective heat spreaders 208 of the plural discrete die-heat spreader assemblies 220, and to planarize a top surface of the multichip module 1700.

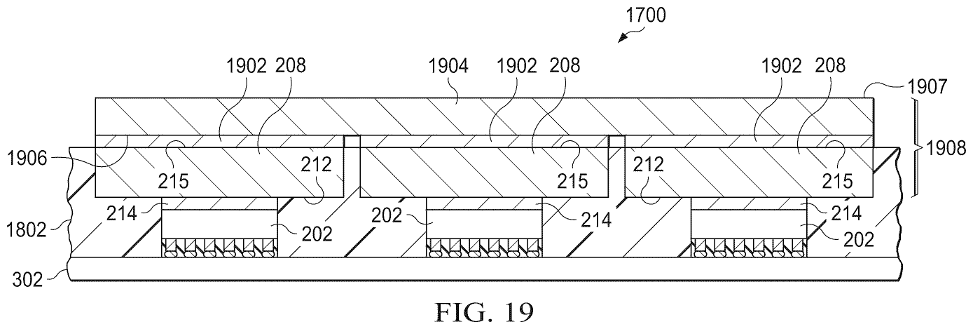

The method 1600 proceeds to block 1606 where a continuous heat spreader 1904 is attached to each of the plural discrete die-heat spreader assemblies 220 attached to the substrate 302. Referring to FIGS. 18 and 19, in an embodiment of block 1606, each of the plural discrete die-heat spreader assemblies 220 is attached to the same continuous heat spreader 1904 via exposed top surfaces of each of the plural die-heat spreader assemblies 220 (e.g., which includes the exposed bottom surfaces 215 of each of the plural discrete heat spreaders 208). The continuous heat spreader 1904, like the examples discussed above, may include a SiC heat spreader, a Cu heat spreader, a CPC heat spreader, or an AlN heat spreader, among others.

As part of the attachment process of block 1606, a surface 1906 of the continuous heat spreader 1904, which is substantially flat (e.g., without cavities), may be coated with a conductive layer (not shown), such as a Au-plated layer. The conductive layer formed on the surface 1906 of the continuous heat spreader 1904 may be patterned, in some examples, using a combination of photolithographic patterning and etching (e.g., such as using Au etching, laser ablation, or the like), such that the patterned conductive layer includes patterned regions corresponding to, and having similar surface areas as, the top surfaces of each of the plural die-heat spreader assemblies 220 (e.g., the bottom surfaces 215 of each of the plural discrete heat spreaders 208). In some embodiments, a Au/Ni layer may be deposited (e.g., by sputter deposition) onto top surfaces of each of the plural die-heat spreader assemblies 220, surfaces which were previously subject to the grinding process, in order to ensure compatibility of the surface with a subsequently formed thermally conductive bonding layer. Specifically, a thermally conductive bonding layer 1902, similar to the thermally conductive bonding layer 214 discussed above, may then be used to attach the top surfaces of each of the plural die-heat spreader assemblies 220, which include the sputtered Au/Ni layer, to the patterned conductive layer on the surface 1906 of the continuous heat spreader 1904, after appropriate positioning and aligning of the continuous heat spreader 1904 over the top surfaces of each of the plural die-heat spreader assemblies 220. In at least some cases, the thermally conductive bonding layer 1902 includes a silver (Ag) sinter paste. A reflow or curing process may then be performed to complete the bond between the plural die-heat spreader assemblies 220 and the continuous heat spreader 1904 to form a stacked heat spreader assembly 1908.

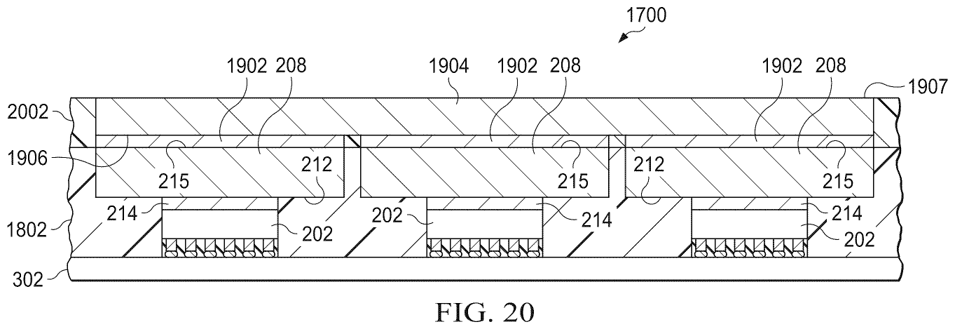

The method 1600 proceeds to block 1608 a second molding process is performed, similar to the molding process of block 108 of method 100, discussed above. Referring to FIGS. 19 and 20, in an embodiment of block 1608, a mold compound 2002 (similar to the mold compound 224, discussed above) may be formed surrounding the thermally conductive bonding layer 1902 and the continuous heat spreader 1904 to encapsulate thermally conductive bonding layer 1902 and the continuous heat spreader 1904. Recall that the plural die-heat spreader assemblies 220 were previously encapsulated by the mold compound 1802 formed by the first molding process of block 1604. In some embodiments, the mold compound 2002 may include a mold compound formed by a film-assisted molding (FAM) process, or by another suitable process. In some cases, the mold compounds 1802, 2002 may be composed of a similar material. In other cases, the mold compounds 1802, 2002 may be composed of different materials. In some examples, after forming the mold compound 2002 and in some embodiments, a surface 1907 of the continuous heat spreader 1904 (opposite the surface 1906) may be substantially level with a top surface of the mold compound 2002. However, regardless of whether the surface 1907 of the continuous heat spreader 1904 and the top surface of the mold compound 2002 are level with each other, the surface 1907 of the continuous heat spreader 1904 may remain exposed after formation of the mold compound 2002, thereby providing a thermal path for transferring heat away from the plurality of IC die 202. Moreover, in some cases, an external heat sink (e.g., such as shown and described with reference to FIG. 5A) may optionally be attached to the exposed surface 1907 of the continuous heat spreader 1904.

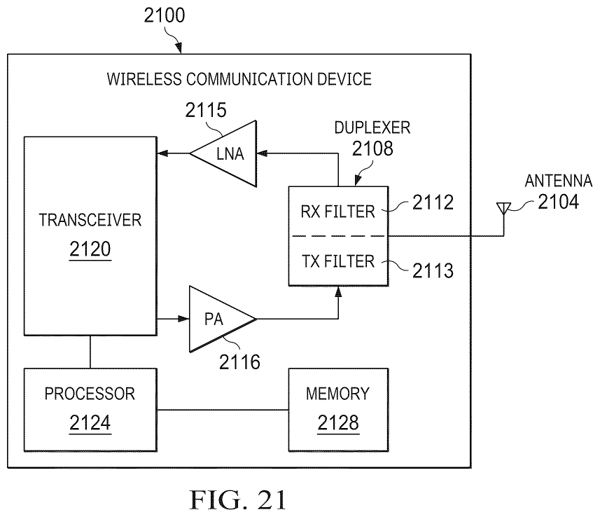

High-power GaN RF devices, implemented in accordance with the various embodiments disclosed herein, may be employed in a wide range of applications such as in radars, telecommunications, base stations, power amplifiers, etc. As merely one example, and with reference to FIG. 21, illustrated therein is a wireless communication device 2100, which implements the discrete chip module 200, the multichip module 600, the multichip module 800, the multichip module 1200, the multichip module 1500, and/or the multichip module 1700. The wireless communication device 2100 may have an antenna 2104, a duplexer 2108 (containing an RX filter 2112 and a TX filter 2113), a power amplifier (PA) 2116, a low noise amplifier (LNA) 2115, a transceiver 2120, a processor 2124, and a memory 2128 coupled with each other at least as shown.

The antenna 2104 may include one or more antennas to transmit and receive radio frequency (RF) signals over the air. The antenna 2104 may be coupled with the duplexer 2108 that operates to selectively couple the antenna 2104 with the LNA 2115 or the PA 2116. When transmitting outgoing RF signals, the TX filter 2113 may couple the antenna 2104 with the PA 2116. When receiving incoming RF signals, the RX filter 2112 may couple the antenna 2104 with the LNA 2115. In some embodiments, the RX and TX filters 2112 and 2113 may include a first plurality of series resonators and a second plurality of resonators. The RX filter 2112 may filter the RF signals received from the antenna 2104 and pass portions of the RF signals within a predetermined bandpass to the transceiver 2120.

When transmitting outgoing RF signals, the duplexer 2108 may couple the antenna 2104 with the PA 2116. The PA 2116 may receive RF signals from the transceiver 2120, amplify the RF signals, and provide the RF signals to the antenna 2104 for over-the-air transmission. The PA 2116 may include one or more high-power RF devices implemented within one or more of the discrete chip module 200, the multichip module 600, the multichip module 800, the multichip module 1200, the multichip module 1500, and/or the multichip module 1700.

The processor 2124 may execute a basic operating system program, stored in the memory 2128, in order to control the overall operation of the wireless communication device 2100. For example, the processor 2124 may control the reception of signals and the transmission of signals by transceiver 2120. The processor 2124 may be capable of executing other processes and programs resident in the memory 2128 and may move data into or out of the memory 2128, as desired by an executing process.

The transceiver 2120 may receive outgoing data (e.g., voice data, web data, e-mail, signaling data, etc.) from the processor 2124, may generate RF signals to represent the outgoing data, and provide the RF signals to the PA 2116. Conversely, the transceiver 2120 may receive RF signals from the RX filter 2112 that represent incoming data. The transceiver 2120 may process the RF signals and send incoming signals to the processor 2124 for further processing.

In various embodiments, the wireless communication device 2100 may be, but is not limited to, a mobile telephone, a paging device, a personal digital assistant, a text-messaging device, a portable computer, a desktop computer, a base station, a subscriber station, an access point, a radar, a satellite communication device, or any other device capable of wirelessly transmitting/receiving RF signals.

Those skilled in the art will recognize that the wireless communication device 2100 is given by way of example and that, for simplicity and clarity, only as much of the construction and operation of the wireless communication device 2100 as is necessary for an understanding of the embodiments is shown and described. Various embodiments contemplate any suitable component or combination of components performing any suitable tasks in association with wireless communication device 2100, according to particular needs. Moreover, it is understood that the wireless communication device 2100 should not be construed to limit the types of devices in which the embodiments disclosed herein may be implemented.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip module, comprising:
a package substrate;
an integrated circuit (IC) die attached to the package substrate; and
a heat spreader coupled to a backside of the IC die, wherein the IC die has a first surface area, and wherein the heat spreader has a second surface area that is at least twice as large as the first surface area.

2. The chip module of claim 1, wherein the second surface area that is 2-3 times larger than the first surface area.

3. The chip module of claim 1, wherein the heat spreader is coupled to the backside of the IC die along a first surface of the heat spreader, the first surface being substantially flat.

4. The chip module of claim 1, further comprising one or more surface mount devices (SMDs) attached to the package substrate in regions of the package substrate underneath portions of the heat spreader that overhang lateral ends of the IC die.

5. The chip module of claim 1, wherein the heat spreader is coupled to the backside of the IC die through a wafer-level bond including a thermally conductive bonding layer.

6. The chip module of claim 1, wherein the heat spreader comprises a SiC heat spreader, a Cu heat spreader, a CPC heat spreader, or an AlN heat spreader.

7. The chip module of claim 1, wherein the coupled heat spreader and IC die collectively provide a die-heat spreader assembly, and wherein the die-heat spreader assembly is attached to the package substrate along a frontside of the IC die.

8. The chip module of claim 1, wherein the coupled heat spreader and IC die collectively provide a die-heat spreader assembly, and wherein the chip module further comprises a mold compound that encapsulates the die-heat spreader assembly while a top surface of the die-heat spreader assembly remains exposed.

9. The chip module of claim 8, further comprising an external heat sink coupled to the exposed top surface of the die-heat spreader assembly.

10. A method, comprising:
attaching a backside of a die to a first surface of a heat spreader to form a die-heat spreader assembly, wherein the heat spreader has a first surface area that is at least twice as large as a second surface area of the die;
bonding the die-heat spreader assembly to a substrate, wherein the die-heat spreader assembly is bonded to the substrate along a frontside of the die; and
performing a molding process to encapsulate the die-heat spreader assembly, wherein after the molding process a second surface of the heat spreader, opposite the first surface of the heat spreader, remains exposed.

11. The method of claim 10, wherein the first surface area is 2-3 times larger than the second surface area.

12. The method of claim 10, wherein the first surface of the heat spreader is substantially flat.

13. The method of claim 10, further comprising prior to the performing the molding process, attaching one or more surface mount devices (SMDs) to the substrate in regions of the substrate underneath portions of the heat spreader that overhang lateral ends of the die.

14. The method of claim 10, further comprising prior to the performing the molding process, performing an underfill process to fill gaps between the die and the substrate.

15. The method of claim 10, further comprising after performing the molding process, coupling an external heat sink to the exposed second surface of the heat spreader.

16. The method of claim 15, wherein the attaching the backside of the die to the first surface of the heat spreader comprises a wafer-level bonding process, and wherein the coupling the external heat sink to the exposed second surface of the heat spreader comprises a package level bonding process.

17. A wireless communication device, comprising:
an antenna;
a duplexer coupled to the antenna; and
a power amplifier selectively coupled to the antenna through the duplexer;
wherein the power amplifier includes an integrated circuit (IC) die disposed within a chip module, and wherein the chip module comprises:
the IC die attached to a substrate; and
a heat spreader coupled to a backside of the IC die, wherein the IC die has a first surface area, and wherein the heat spreader has a second surface area that is at least twice as large as the first surface area.

18. The wireless communication device of claim 17, wherein the IC die includes a high-power radio frequency (RF) device.

19. The wireless communication device of claim 17, wherein the chip module further comprises one or more surface mount devices (SMDs) attached to the substrate in regions of the substrate underneath portions of the heat spreader that overhang lateral ends of the IC die.

20. The wireless communication device of claim 17, wherein the heat spreader comprises a SiC heat spreader, a Cu heat spreader, a CPC heat spreader, or an AlN heat spreader.
